(19) United States
(12) Patent Application Publication
(10) Pub. No.: US 2023/0403451 A1
(43) Pub. Date: Dec. 14, 2023

(54) SYSTEM AND APPARATUS OF UNDER-DISPLAY CAMERA

(71) Applicant: GOOGLE LLC, Mountain View, CA (US)

(72) Inventors: Chung Chun WAN, Mountain View, CA (US); Chad SEGUIN, Mountain View, CA (US)

(21) Appl. No.: 18/033,603

(22) PCT Filed: Oct. 27, 2020
(86) PCT No.: PCT/US2020/070699

§ 371 Date: Apr. 25, 2023

(51) Int. Cl. H04N 23/55; H04N 23/95; H04N 23/16; H04M 1/02; H10K 59/35; H10K 59/126

(52) U.S. Cl. CPC H04N 23/55; H04N 23/95; H04N 23/16; H10K 59/126; H04M 1/0266; H10K 59/353; H04M 1/0264

(57) ABSTRACT

A device including a display including a main portion, a first region and a second region being in different positions within a boundary of the main portion, the first region having a first structure of light-blocking, and the second region having a second structure of light-blocking elements, a first light sensor positioned under the first region, the first light sensor being configured to capture a first image having at least one first characteristic, wherein the first characteristic depends on the first structure, a second light sensor positioned under the second region, the second light sensor being configured to capture a second image having at least one second characteristic, wherein the second characteristic depends on the second structure, and a memory including code that when executed by a processor causes the processor to generate a third image based on the first image and the second image.

### FIELD

Embodiments relate to cameras in computing devices.

### BACKGROUND

Computing devices (e.g., mobile phones, tablets, etc.) can include one more emissive displays. Expanding a display to cover more area of a computing device may be desirable from, at least, a user experience standpoint. However, electro-optical devices positioned on a side of the mobile device that also includes the display (e.g., a front-facing camera) may compete for real estate on the side of the device that includes the display. Thus, in conventional computing devices cameras that share a surface of computing device with a display are generally positioned outside of the light-emitting display portion of the surface, although the cameras may be positioned under a transparent surface element (e.g., a cover window layer) that also is part of the light-emitting display of the computing device. In such a configuration, light can pass through a portion of the transparent surface element to reach the camera, and this portion can appear as, or can be referred to as, a notch, a cutout, a punch hole, etc. in the light-emitting display. However, the existence of the notch, cutout, or punch hole reduces the area of, and causes an irregular shape to, the light-emitting display on the surface of the computing device.

### SUMMARY

In a general aspect, a device, a system, a non-transitory computer-readable medium (having stored thereon computer executable program code which can be executed on a computer system), and/or a method can perform a process with a device including a display including a main portion, a first region and a second region, the first region and the second region being in different positions within a boundary of the main portion, the first region having a first structure of light-blocking elements that distort light transmitted through the display, and the second region having a second structure of light-blocking elements that distort light transmitted through the display differently as compared to the first structure, a first light sensor positioned under the first region, the first light sensor being configured to capture a first image having at least one first characteristic, wherein the first characteristic depends on the first structure, a second light sensor positioned under the second region, the second light sensor being configured to capture a second image having at least one second characteristic, wherein the second characteristic depends on the second structure, and a memory including code that when executed by a processor causes the processor to generate a third image based on the first image and the second image.

Implementations can include one or more of the following features. For example, the first structure and the second structure can be based on a layout of red, green, and blue light-emitting diodes (LEDs) in the display. The first structure and the second structure can be based on a shape of at least one LED in an LED layer of the display. The display can include a plurality of layers, and one of the plurality of layers can include the light-blocking elements of the first region and the light-blocking elements of the second region. The first region can include a layout of a first array of LEDs of a first shape having a first arrangement of open space between the LEDs of the first array configured to allow light to pass through the display, the second region can include a layout of a second array of LEDs of a second shape having a second arrangement of open space between the LEDs of the second array to allow light to pass through the display, the first arrangement of open space can be configured to have a first transmissivity of light passing through the display, the second arrangement of open space can be configured to have a second transmissivity of light passing through the display, and the first transmissivity can be different than the second transmissivity.

The first light sensor can be a monochrome sensor, the second light sensor can be a color sensor, light-blocking elements of the first structure can include rectangular shaped elements, and light-blocking elements of the second structure can include circular shaped elements. The rectangular shaped elements can include first rectangle shaped elements having first dimensions and a second rectangle shaped elements having second dimensions, and the circular shaped elements can include first circular shaped elements having a first diameter and second circular shaped elements having a second diameter. The at least one first characteristic can include one or more of quality, sharpness, and distortion, and the at least one second characteristic can include one or more of quality, sharpness, and distortion. The code can include a machine learned model having at least one convolution layer.

In another general aspect, a device, a system, a non-transitory computer-readable medium (having stored thereon computer executable program code which can be executed on a computer system), and/or a method can perform a process with a method including generating a first image having at least one first characteristic based on a first sensor sensing light through a first region of a display, the first region having a first structure configured to impact light traversal through the display, generating a second image having at least one second characteristic based on a second sensor sensing light through a second region of the display, the second region having a second structure configured to impact the light traversing through the display differently as compared to the first structure, and generating a third image based on the first image and the second image.

Implementations can include one or more of the following features. For example, the at least one first characteristic can include one or more of quality, sharpness, and distortion, and the at least one second characteristic can include one or more of quality, sharpness, and distortion. The generating of the third image can include using a machine learned model having at least one convolution layer. The first light sensor can be one of a color sensor, a monochrome sensor, or an infrared sensor, and the second light sensor can be one of a color sensor, a monochrome sensor, or an infrared sensor. The first sensor can be a monochrome sensor, the second sensor can be a color sensor, a layout of the first structure can include rectangular shaped elements, and a layout of the second structure can include circular shaped elements.

The rectangular shaped elements can include first rectangular shaped elements having first dimensions and a second rectangle having second dimensions, and the circular shaped elements can include first circular shaped elements having a first diameter and a second circle having a second diameter. The light through the first region can be distorted based on the first structure, and the light through the second region can be distorted based on the second structure. The first region can include a layout of a first array of LEDs of a first shape having a first arrangement of open space between the LEDs of the first array configured to allow light to pass through the display, the second region can include a layout of a second array of LEDs of a second shape having a second arrangement of open space between the LEDs of the second array to allow light to pass through the display, the first arrangement of open space can be configured to have a first transmissivity of light passing through the display, the second arrangement of open space can be configured to have a second transmissivity of light passing through the display, and the first transmissivity can be different than the second transmissivity.

In yet another general aspect, a device, a system, a non-transitory computer-readable medium (having stored thereon computer executable program code which can be executed on a computer system), and/or a method can perform a process with a system including a display including a main portion, a first region and a second region, the first region and the second region being in different positions within a boundary of the main portion, the first region having a first structure of light-blocking elements that distort light transmitted through the display, and the second region having a second structure of light-blocking elements that distort light transmitted through the display differently as compared to the first structure, a monochrome sensor positioned under the first region, the monochrome sensor being used to capture a monochrome image having at least one first characteristic, a color sensor positioned under the second region, the color sensor being used to capture a color image having at least one second characteristic and a memory storing a set of instructions and a processor configured to execute the set of instructions to cause the system to generate a third image based on the monochrome image and the color image.

Implementations can include one or more of the following features. For example, a layout of the first structure can include rectangular shaped elements and a layout of the second structure can include circular shaped elements. The rectangular shaped elements can include a first rectangle having first dimensions and a second rectangle having second dimensions, and the circular shaped elements can include a first circle having a first diameter and a second circle having a second diameter.

### BRIEF DESCRIPTION OF THE DRAWINGS

Example embodiments will become more fully understood from the detailed description given herein below and the accompanying drawings, wherein like elements are represented by like reference numerals, which are given by way of illustration only and thus are not limiting of the example embodiments and wherein:

FIG. 1A illustrates a first camera configuration on a mobile device.

FIG. 1B illustrates a second camera configuration on a mobile device.

FIG. 1C illustrates a third camera configuration on a mobile device.

FIG. 1D illustrates a camera configuration on a mobile device according to at least one example embodiment.

FIG. 2 illustrates a block diagram of a signal flow for processing an image according to at least one example embodiment.

FIG. 3 illustrates a block diagram of a signal flow for processing an image according to at least one example embodiment.

FIG. 4A is a schematic diagram an implementation of a display panel 400 and a sensor 402 located under the display panel

FIGS. 4B-4E depicts a top (front) view of pixels and signal lines of a portion of an emissive display according to at least one example embodiment.

FIGS. 4F-4K illustrate possible sub-pixel layouts according to at least one example embodiment.

FIGS. 5A and 5B illustrate images captured using different display layers with the same sensor configuration according to at least one example embodiment.

FIG. 6A illustrates a block diagram of an image processing system according to at least one example embodiment.

FIG. 6B illustrates a block diagram of a module of the image processing system according to at least one example embodiment.

FIG. 7A illustrates layers in a convolutional neural network with no sparsity constraints.

FIG. 7B illustrates layers in a convolutional neural network with sparsity constraints.

FIG. 8 illustrates a block diagram of a model according to an example embodiment.

FIG. 9 illustrates a block diagram of a method for performing image fusion according to at least one example implementation.

FIG. 10 shows an example of a computer device and a mobile computer device according to at least one example embodiment.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

As descried herein, to eliminate the notch, cutout, or punch hole in a display, while also allowing for the transmission of light to a camera, computing devices can include an emissive display having one or more portion(s) through which light is transmitted to reach a one or more camera sensors located under the emissive display. In such a configuration, the portion of the display through which light is transmitted to the camera sensor(s) functions as a portion of the light-emitting display of the computing device. However, the light-emitting display includes opaque and diffractive elements that distort light as the light is transmitted through the portion(s) of the display above the camera sensor(s). To mitigate the impact of the distortion of light that reaches the camera sensor(s) on images formed by the sensor(s), particular patterns of opaque and diffracting elements can be used in the portion of the display above the camera sensors(s), which patterns may be different than the pattern of opaque and diffracting elements used in other portions of the display. Further, a type of camera sensor can be selected for use under a portion (or region) of the display based on the particular patterns of opaque and diffracting elements. In addition, one or more image correction algorithms can be applied to images formed from data captured by camera sensors located under the light-emitting display, where the image correction and/or image fusion algorithms may be based on the fusion of images generated by different camera sensors, at least two of which are located under the light-emitting display.

Thus, example implementations, described herein, allow the emissive display of the computing device display to operate over a large area of the surface of the device, without any notches, cutouts, or punch holes in the emissive display, even when a camera is positioned under the display and receives light that is transmitted through the display. The computing device can include a display having two or more cameras located under the display, and light pass can through one or more portions or regions of the display to reach the camera(s), while the display continues to perform the functions of the display. Such example implementations are preferable to conventional displays, because a user experience is improved when the display performs the functions of the display (e.g., displays images) over a large area of the device and allows the use of a camera without disrupting the operation of the display.

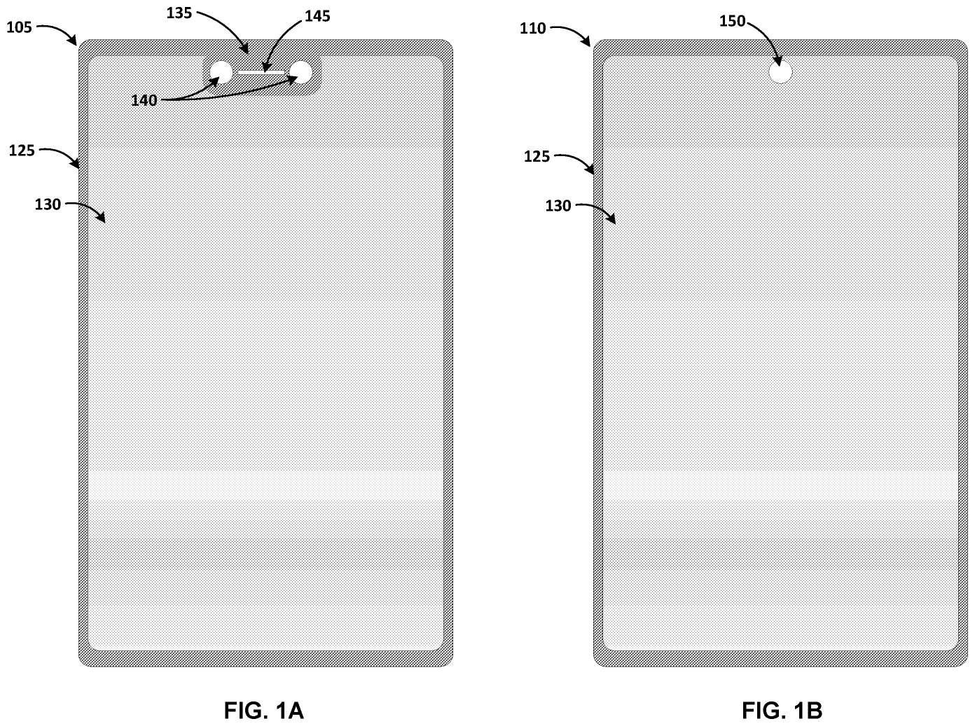

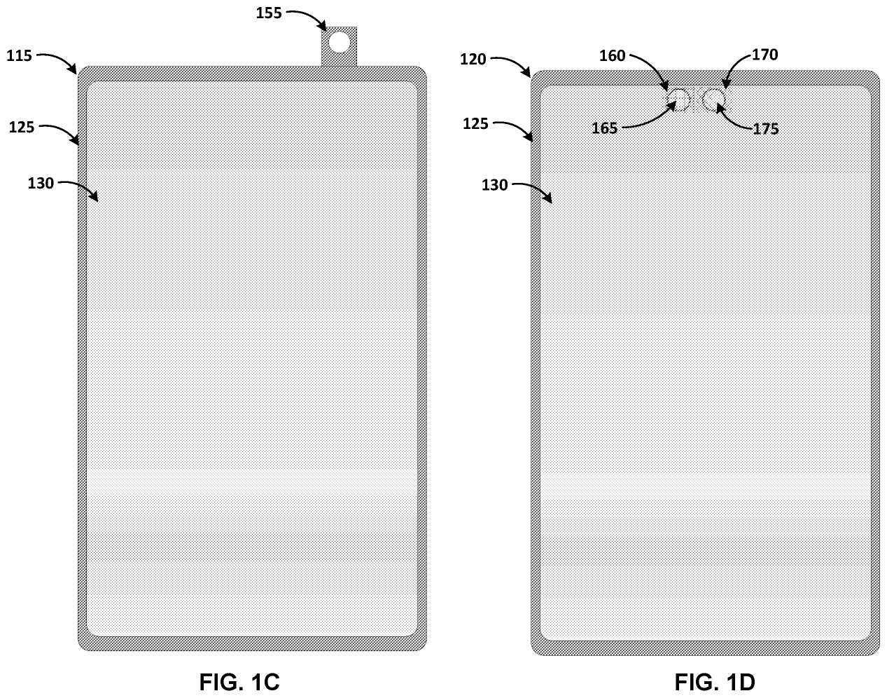

FIG. 1A illustrates a first camera configuration on a mobile device. As shown in FIG. 1A, a device 105 includes a bezel 125, a display 130, a display cutout 135, cameras 140, and a speaker 145. The device 105 can be a mobile device, a cell phone, a tablet, a laptop, and/or the like. The bezel 125 can include a portion of a frame configured to fix the display 130 on the device 105. The display 130 (e.g., an emissive display) can include a display main portion, and the display cutout 135 can include a portion of the surface of the device that does not include emissive display elements. That is, the display cutout 135 can include a portion of the surface of the device that is not part of the display 130. In other words, the display cutout 135 may not be configured to operate (e.g., show text, images, a background, and/or the like) as the display 130 operates. The display cutout 135 can be configured to provide a location to place the cameras 140 and the speaker 145, such that the camera can take a picture of a scene without the display 130 distorting (e.g., blocking, redirecting, and/or the like) light.

FIG. 1B illustrates a second camera configuration on a mobile device. As shown in FIG. 1B, a device 110 includes the bezel 125, the display 130, a display punch hole 150, and the camera 140. The device 110 can be a mobile device, a cell phone, a tablet, a laptop, and/or the like. The bezel 125 can include a portion of a frame configured to fix the display 130 on the device 110. The display 130 can include a display main portion, and the display punch hole 150 can include a portion of the display 130. The display punch hole 150 can include a portion of the display 130 that does not include emissive elements (e.g., LEDs). In other words, the display punch hole 150 may not be configured to operate (e.g., show text, images, a background, and/or the like) as the display 130 operates. The display punch hole 150 can be configured to provide a location to place the camera 140 such that the camera can take a picture of a scene without the display 130 distorting (e.g., blocking, redirecting, and/or the like) light transmitted through the hole.

FIG. 1C illustrates a third camera configuration on a mobile device. As shown in FIG. 1C, a device 115 includes the bezel 125, the display 130, a display extension 155, and the camera 140. The device 115 can be a mobile device, a cell phone, a tablet, a laptop, and/or the like. The bezel 125 can include a portion of a frame configured to fix the display 130 on the device 115. The display extension 155 can be configured to provide a location to place the camera 140 such that the camera can take a picture of a scene without the display 130 distorting (e.g., blocking, redirecting, and/or the like) light. The display extension 155 can be configured to extend from the bezel 125 to allow the camera to operate and retract into the device 115 when the camera is not in operation. The display extension 155 can be operably configured to switch between extending from the bezel 125 and retracted into the device 115.

FIG. 1D illustrates a camera configuration on a mobile device according to at least one example embodiment. As shown in FIG. 1D, a device 120 includes the bezel 125, the display 130, a first display region 160, a first camera 165, a second display region 170, and a second camera 175. The device 120 can be a mobile device, a cell phone, a tablet, a laptop, and/or the like. The display 130 can include a display main portion. The first display region 160 can be included in a first portion of the display 130, and the second display region 170 can be included in a second portion of the display 130.

In an example implementation, the first display region 160 can have a structure (e.g., layout pattern or shape of light-emitting devices of the display or of transistors that drive the light-emitting devices) that can allow light to pass through the display 130. The first display region 160 can have a structure that causes light to be distorted (e.g., blocked, diffracted, redirected, etc.) when it is transmitted through the first display region 160. The second display region 170 can have a structure (e.g., layout pattern or shape of light-emitting devices of the display or of transistors that drive the light-emitting devices) that can allow light to pass through the display 130. The second display region 170 can have a structure that causes light to be distorted (e.g., blocked, diffracted, redirected, etc.) when it is transmitted through the region 170. The first display region 160 can cause light to be distorted differently than the second display region 170 distorts light.

In an example implementation, camera 165 and camera 175 each can be configured as under-display cameras. Camera 165 and camera 175 can be positioned under the first display region 160 and the second display region 170, respectively. Camera 165 and camera 175 can have different light sensitivity. For example, camera 165 can have a lower light sensitivity as compared to camera 175.

In an example implementation, camera 165 can include an RGB sensor, and the first display region 160 can have a circular LED or transistor layout structure. Furthermore, camera 175 can include a monochrome sensor, and the second display region 170 can have a rectangular LED or transistor layout structure. The combination of an RGB sensor and a circular layout structure can generate signals causing an image to have a first characteristic(s) (e.g., quality, sharpness, distortion, and the like) based on light distortion and camera sensitivity. The combination of a monochrome sensor and a rectangular layout structure can generate signals that can generate signals causing an image to have a second characteristic(s) (e.g., quality, sharpness, distortion, and the like) based on light distortion and camera sensitivity. For example, the rectangular layout structure allows more light to pass through and also generates images with better sharpness, and the monochrome sensor is more suitable than the RGB sensor to pick up these characteristics. Overall, the first display-sensor combination and the second display-sensor combination can be designed to pick up first and second characteristics that are complementary to each other. The two images can be fused afterwards so that the resulting image has both complementary characteristics.

The display configuration of device 120 can allow the display 130 to operate (e.g., show text, images, a background, and/or the like) over the entirety of the display 130. In other words, the first display region 160 includes LEDs and/or transistors that drive the LEDs, and the second display region 170 includes LEDs and/or transistors that drive the LEDs. The LEDs and/or transistors can be used throughout the display 130 to enable operation (e.g., the emission of light) of the display 130. The display configuration of device 120 is preferable over the display configuration of device 105 and the display configuration of device 110, because device 105 and device 110 omit LEDs and/or transistors that drive LEDs from a notch or punch hold in a portion of the display. Therefore, the display configuration of device 105 and device 110 do not allow the display 130 to operate (e.g., show text, images, a background, and/or the like) over the display area as large as the display area of device 120. The display configuration of device 120 is preferable over the display configuration of device 115, at least, because there are no moving parts associated with placing a camera in a position to capture an image of a scene in device 120 and there are moving parts associated with placing a camera in a position in device 115 in order to capture an image of a scene.

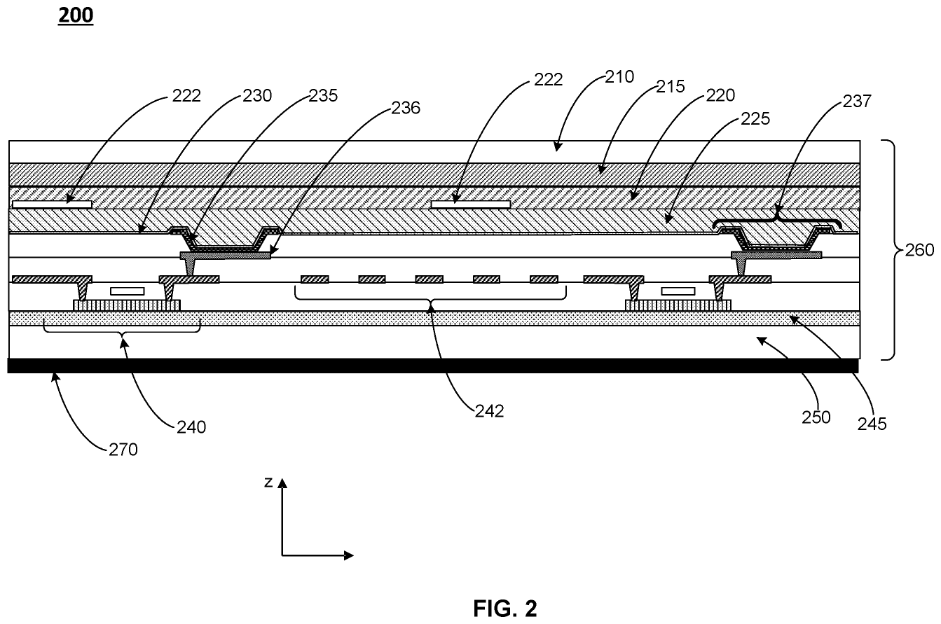

FIG. 2 illustrates a side, cross-sectional view of an emissive display (e.g., an AMOLED display) suitable for use with the mobile device of FIGS. 1A-1D. While the principles of the disclosure may be applied to display technologies other than AMOLED displays, the implementation of an AMOLED display will be considered throughout the disclosure.

As shown in FIG. 2, the display 200 (e.g., an AMOLED display) includes a plurality of layers that make up a display panel 260. The layers include a cover glass layer 210 that can form the front surface of the mobile device (e.g., device 120). In a possible implementation, the display 200 can include a polarizer film layer 215. The display 200 can also include a touch sensor layer 220 that includes touch sensor electrodes 222. The display 200 can also include a pixel circuit layer 225. Pixels 237 for the display are formed from a cathode layer 230, an OLED emitter stack 235, and separate elements of an anode layer 236. Elements of the anode layer 236 may be reflective so that light emitted from the OLED emitter stack 235 is directed in a vertical (z) direction from the anode layer 236.

An element of the anode layer 236 can be coupled to a thin film transistor (TFT) semiconductor structure 240 that includes a source, a gate, and a drain, which can be controlled by electrical signals transmitted over signal lines 242. The display 200 can further include a transparent barrier layer 245 that includes, for example, SiNx or SiONx and a transparent substrate layer 250 that includes, for example, polyimide (PI) and/or polyethylene terephthalate (PET). An opaque layer/film 270 for mechanical support, heat spreading, and electrical shielding can be located below the display panel 260 to protect the display from localized hot spots due to heat-generating elements in the mobile device, such as, for example, a CPU, a GPU, etc., as well as from electrical signals/electrical noise from electrical components in the device located below the display 200. As discussed in more detail below, transparent openings may be created in the opaque layer/film 270 to allow light to pass through display 200 to reach a camera sensor located below the display 200.

The layers of the display 200 may include transparent and non-transparent circuit elements. For example, the TFT structure 240, the pixels 237, the signal lines 242, and/or touch sensor electrodes 222 may all block light from propagating through the display 200. Light can be either reflected or absorbed by the non-transparent (i.e., opaque) circuit elements. In an example implementation, the TFT structure 240 associated with the pixels 237 can be varied in portions or regions of the display 200. Varying the TFT structure 240 can include varying a layout of the pixels 237, the signal lines 242 and/or touch sensor electrodes 222, a shape of the pixels 237 and/or touch sensor electrodes 222, a proximity of at least two of the pixels 237, at least two of the signal lines 242 and/or at least two of the touch sensor electrodes 222, a space between at least two of the pixels, at least two of the signal lines 242 and/or at least two of the touch sensor electrodes 222, and/or the like. Varying the TFT structure 240 can impact (or influence) light transmitted (or traversing) through the display 200. For example, the light can be blocked by the pixels 237 (e.g., the pixels 237 can be opaque) or refracted by the pixels 237 (e.g., a shape of the pixels 237 can influence refraction of light).

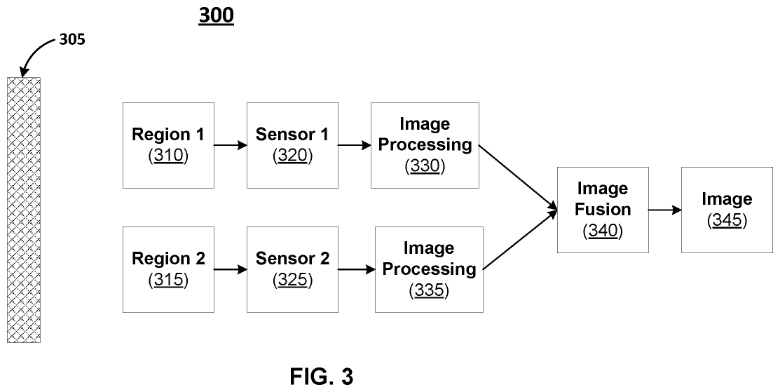

FIG. 3 illustrates a block diagram of a signal flow for processing an image according to at least one example embodiment. As shown in FIG. 3, the signal flow 300 includes a region 1 310 block, a region 2 315 block, a sensor 1 320 block, a sensor 2 325 block, an image processing 330 block, an image processing 335 block, an image fusion 340 block, and an image 345 block. The signal flow 300 can be configured to generate image 345 based on at least a portion of scene 305.

Region 1 310 and region 2 315 can each be included in a portion of a device (e.g., a mobile device, a tablet, a laptop, and/or the like) display (e.g., display 200). Region 1 310 and region 2 315 can be included in a main display portion of the device display. Region 1 310 and region 2 315 can have a different structure (e.g., a different TFT structure 240) as compared to each other and the main display portion.

The device can include at least one camera positioned under the display. Sensor 1 320 and sensor 2 325 each can be configured as an under-display camera. Sensor 1 320 and sensor 2 325 can be positioned under region 1 310 and region 2 315, respectively. Sensor 1 320 and sensor 2 325 can have different light sensitivity. For example, sensor 1 320 can have a lower light sensitivity as compared to sensor 2 325. The lower light sensitivity of sensor 1 320 can be compensated by using a more transmissive display or display portion. Accordingly, region 1 310 can have a structure (e.g., layout pattern) that can allow more light to pass through as compared to region 2 315 (and/or the main display portion of the device display).

In an example implementation, the sensor 1 320 and/or sensor 2 325 can include a color sensor, a monochrome (e.g., black and white, grayscale, and/or the like) sensor, an infrared sensor, and/or the like. A color sensor can be configured to detect light in the visible spectrum emitted from a target scene (e.g., scene 305). The color sensor detects one of several primary colors (e.g., red (R), green (G) and blue (B)) at each photosite (e.g., pixel) in an alternating pattern, using a color filter array (CFA). A monochrome sensor can be configured to detect light in the visible spectrum emitted from a target scene (e.g., scene 305). The monochrome sensor can be configured to detect substantially all incoming light at each photosite (e.g., pixel) regardless of color. Therefore, each photosite of the monochrome sensor receives up to 3 times (3X) more light compared to the color sensor. An infrared sensor can be configured to detect infrared radiation emitted from a target scene (e.g., scene 305). For example, the infrared sensor can be configured to detect mid wave infrared wave bands (MWIR), long wave infrared wave bands (LWIR), and/or other thermal imaging bands.

The device can include an image processing pipeline. Image processing 330 and image processing 335 can include portions of the image processing pipeline. Image processing 330 and/or image processing 335 can be configured to generate a color image including three values (e.g., RGB) or one luma and two chrominance (e.g., YUV)) based on the light detected by the sensor (e.g., sensor 1 320 and/or sensor 2 325 respectively). Alternatively, image processing 330 and/or image processing 335 can be configured to generate a monochrome (e.g., black and white, grayscale, and/or the like) image based on the light detected by the sensor (e.g., sensor 1 320 and/or sensor 2 325 respectively). Alternatively, image processing 330 and/or image processing 335 can be configured to generate an infrared image based on the infrared radiation detected by the sensor (e.g., sensor 1 320 and/or sensor 2 325 respectively).

The image fusion 340 block can be configured to generate an image 345 based on the fusion of an image received from the image processing 330 with an image received from image processing 335. Fusing the two images can include using a machine learned (ML) model or algorithm. The ML model can be trained using images captured using sensor and region structure combinations.

In an example implementation, sensor 1 320 can include an RGB sensor and region 1 310 can have a circular LED or transistor layout structure. Furthermore, sensor 2 325 can include a monochrome sensor, and region 2 315 can have a rectangular LED or transistor layout structure. The combination of an RGB sensor and a circular layout structure can generate signals causing an image to have a first characteristic(s) (e.g., quality, sharpness, distortion, and the like). For example, the combination of an RGB sensor and a circular layout structure can generate signals based on detected light that can cause the image processing 330 block to generate a color (RGB) image that can be distorted (e.g., blurry) with improved flare performance. The combination of a monochrome sensor and a rectangular layout structure can generate signals causing an image to have a second characteristic(s) (e.g., quality, sharpness, distortion, and the like). For example, the combination of a monochrome sensor and a rectangular layout structure can generate signals based on detected light that can cause the image processing 335 block to generate a monochrome image with improved distortion (e.g., sharpness and signal-to-noise ratio) performance.

The image fusion 340 block can be configured to generate image 345 from a distorted color image and a sharp monochrome image using a ML model trained to generate a sharp color (RGB) image based on the two input images. Therefore, the ML model can be trained using distorted color images and sharp monochrome images.

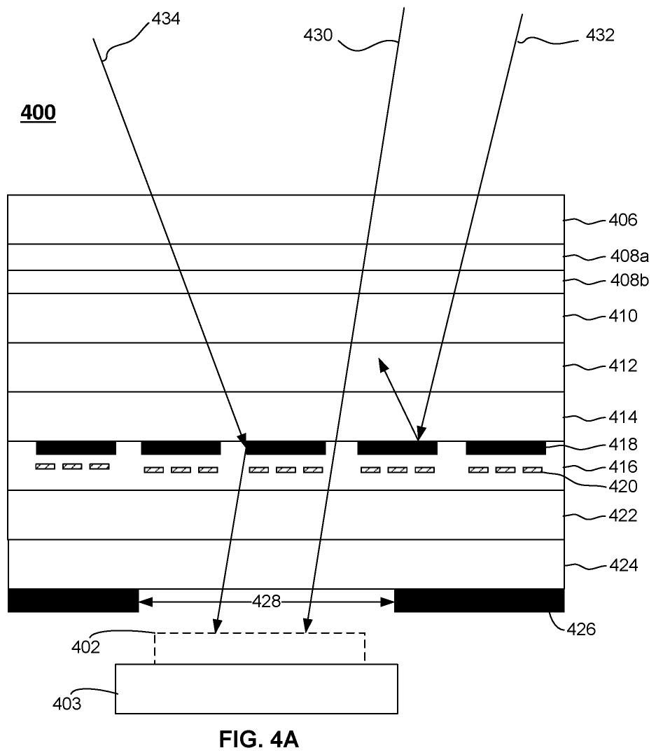

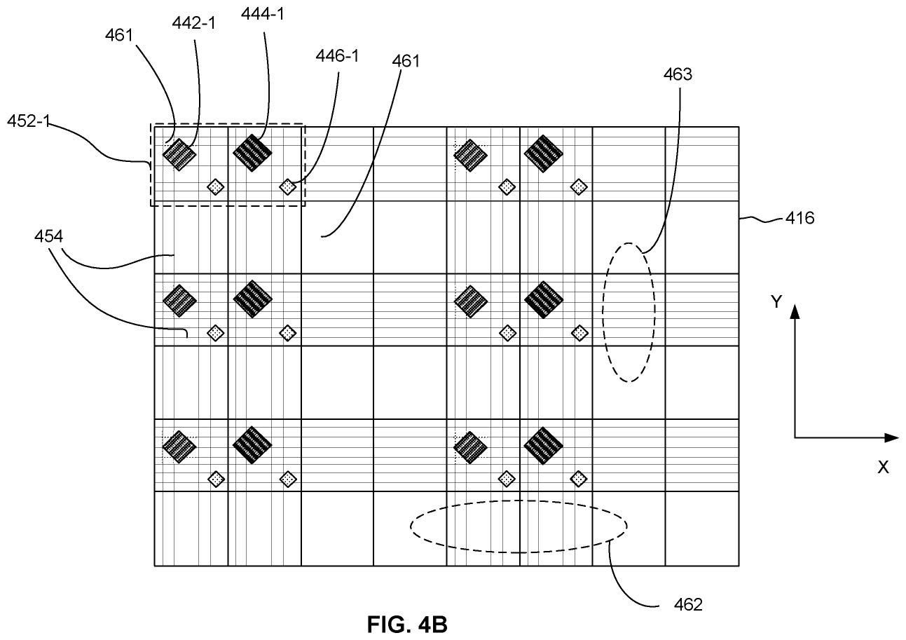

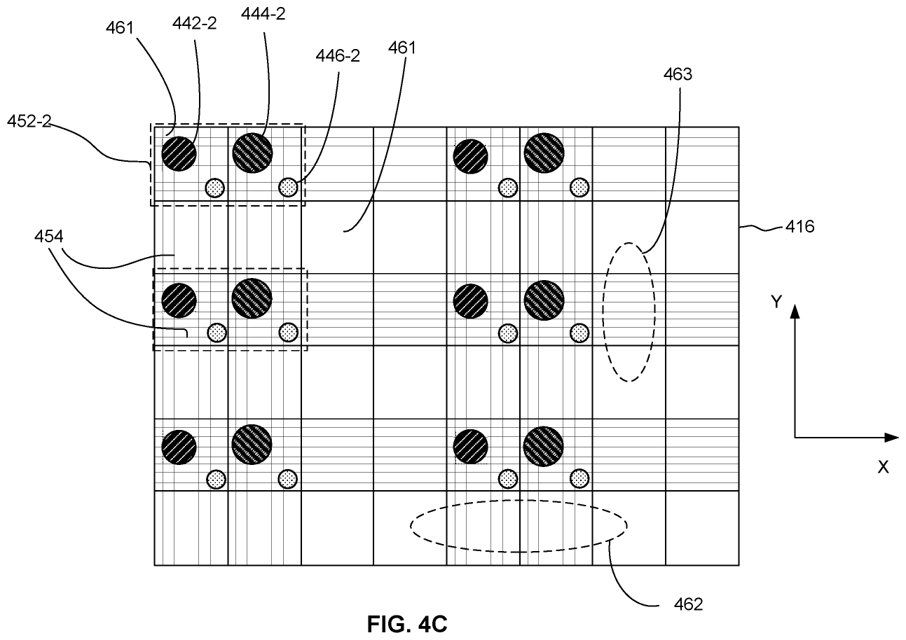

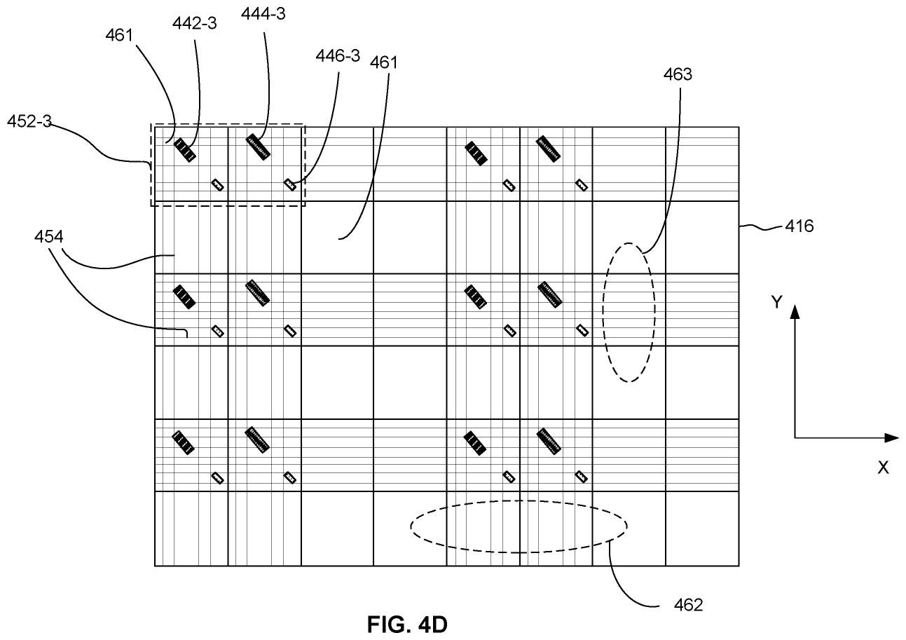

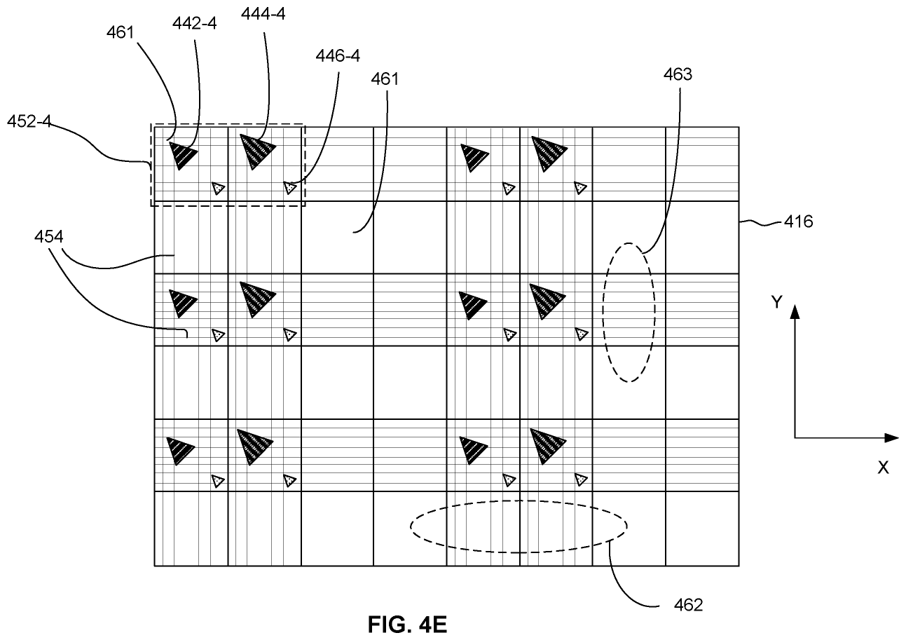

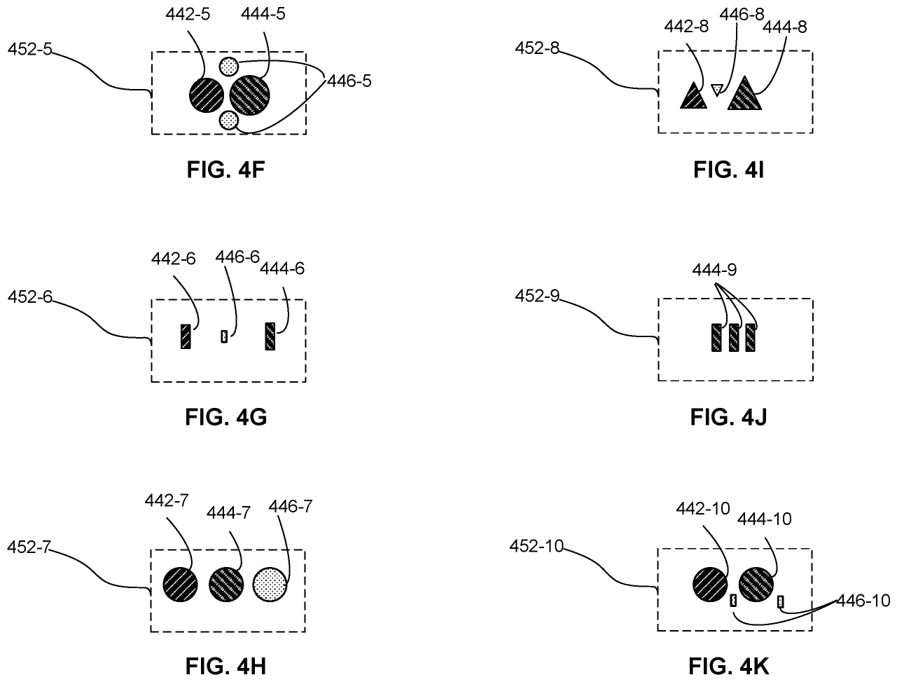

FIG. 4A is a schematic diagram an implementation of a display panel 400 and a sensor 402 located under the display panel 400 illustrating light propagating through the display panel to the sensor. The sensor 402 can be coupled to a sensor module 403 containing control electronics for operating the sensor.

The display panel 400 can include multiple layers. For example, the display panel 400 can include a cover glass layer 406, a polarizer layer that can include a linear polarizer 408a and a quarter-waveplate 408b and that can reduce the amount of light reflected off of an OLED layer in the panel that exits the front surface of the display, an encapsulation/touch sensor layer 410 containing touch sensor electrodes, a cathode layer 412, an OLED layer 414, a pixel circuit layer 416 containing anodes 418 for supplying current to the OLEDs and semiconductor circuit elements 420 for controlling the current provided to the anodes, a PI layer 422, a PET layer 424, and an opaque back cover layer 426. An opening in the back-cover layer 426 allows light from outside the display panel to pass through the panel and through the opening 428 to reach the sensor 402.

Three paths 430, 432, 434 of light passing through the display panel 400 are shown in FIG. 4A, with each path showing a possible reflection of light within the panel. In path 432, light can traverse the transparent elements of the display panel 400 and be reflected by an opaque structure including a top surface of the anodes 418, such that the light is then directed back into the transparent elements of the display panel 400. In another path 430, light can traverse the transparent elements of the display panel 400 and be detected by the sensor 402. The light in path 430 can traverse between two of the anodes 418, such that a significant portion of the energy of the light can be detected by the sensor 402. In path 434, light can traverse the transparent elements of the display panel 400, get refracted by an opaque structure including a side surface of the anodes 418 and be detected by the sensor 402. The refraction of the light in path 434 can depend on a shape of the anodes 418. For example, a shape including a flat surface (e.g., a rectangle, a triangle, and/or the like), can refract the light differently than a curved surface (e.g., a circle).

FIG. 4B depicts a top view of a portion of an emissive display. The portion of the emissive display can be a portion of the pixel circuit layer 416 that includes emissive areas 452-1 that include multiple light-emitting sub-pixels 442-1, 444-1, 446-1 and electrically conductive signal lines 454 providing electrical signals to pixel circuits that drive the sub-pixels. In FIG. 4B, pixels in the display can include a plurality of light emitting elements (e.g., light emitting diodes) that emit different colors, so that all visible colors can be produced by a pixel by mixing amount of light from the different elements. For example, in some implementations, a pixel can include a red LED 442-1, a blue LED 444-1 and two green LEDs 446-1. In FIG. 4B, the sub-pixels 442-1, 444-1, 446-1 in the pixel circuit layer 416 can have the shape of a square. Each square can have different dimensions.

A portion(s) 461 of the display depicted in FIG. 4B can include an arrangement of open space configured to allow light to pass through the display. The open space can have a transmissivity, where transmissivity is a percent (%) of light that makes it though the open space. For example, the portion(s) 461 may allow light to pass through the display, because there are no opaque (or non-transparent) elements, such as signal lines 454, emissive areas 452-1 (including pixels 442-1, 444-1, 446-1), and transistors placed in the portion (e.g., portion(s) 461) of the display. The light passing through the display may interact with (e.g., the traversal (or path taken) and/or transmissivity of the light may be impacted by) some pixels and some signal lines 462 running in a vertical (y) direction or signal lines 463 running in a horizontal (x) direction, which can affect the propagation of light through the display.

FIG. 4C depicts a top view of a portion of an emissive display. The portion of the emissive display can be a portion of the pixel circuit layer 416 that includes emissive areas 452-2 that include multiple light-emitting sub-pixels 442-2, 444-2, 446-2 and electrically conductive signal lines 454 providing electrical signals to pixel circuits that drive the sub-pixels. In FIG. 4C, pixels in the display can include a plurality of light emitting elements (e.g., light emitting diodes) that emit different colors, so that all visible colors can be produced by a pixel by mixing amount of light from the different elements. For example, in some implementations, a pixel can include a red LED 442-2, a blue LED 444-2 and two green LEDs 446-2. In FIG. 4C, the sub-pixels 442-2, 444-2, 446-2 in the pixel circuit layer 416 can have the shape of a circle. Each circle can have a different diameter.

FIG. 4D depicts a top view of a portion of an emissive display. The portion of the emissive display can be a portion of the pixel circuit layer 416 that includes emissive areas 452-3 that include multiple light-emitting sub-pixels 442-3, 444-3, 446-3 and electrically conductive signal lines 454 providing electrical signals to pixel circuits that drive the sub-pixels. In FIG. 4D, pixels in the display can include a plurality of light emitting elements (e.g., light emitting diodes) that emit different colors, so that all visible colors can be produced by a pixel by mixing amount of light from the different elements. For example, in some implementations, a pixel can include a red LED 442-3, a blue LED 444-3 and two green LEDs 446-3. In FIG. 4D, the sub-pixels 442-3, 444-3, 446-3 in the pixel circuit layer 416 can have the shape of a rectangle. Each rectangle can have different dimensions.

FIG. 4E depicts a top view of a portion of an emissive display. The portion of the emissive display can be a portion of the pixel circuit layer 416 that includes emissive areas 452-4 that include multiple light-emitting sub-pixels 442-4, 444-4, 446-4 and electrically conductive signal lines 454 providing electrical signals to pixel circuits that drive the sub-pixels. In FIG. 4E, pixels in the display can include a plurality of light emitting elements (e.g., light emitting diodes) that emit different colors, so that all visible colors can be produced by a pixel by mixing amount of light from the different elements. For example, in some implementations, a pixel can include a red LED 442-4, a blue LED 444-4 and two green LEDs 446-4. In FIG. 4E, the sub-pixels 442-4, 444-4, 446-4 in the pixel circuit layer 416 can have the shape of a triangle. Each triangle can have different dimensions.

In the layout of FIGS. 4B-4E, the density of emissive areas 452 are sparsely illustrated. However, the pixel circuit layer 416 can include a denser layout of emissive areas 452. The pixel circuit layer 416 of the display panel can include a consistent layout of the emissive areas 452 throughout the pixel circuit layer 416 (e.g., in a main portion of the display). In example implements, the pixel circuit layer 416 includes more than one portion, region, area and the like, each having a different emissive areas 452 layout (e.g., a different TFT structure). For example, the pixel circuit layer 416 can include a main portion that includes a significant portion (e.g., almost all) of the pixel circuit layer 416. The main portion of the pixel circuit layer 416 can include an emissive areas 452 layout. The main portion of the pixel circuit layer 416 can include a first region and a second region within the boundaries of the main portion of the pixel circuit layer 416. The first region can include a first emissive areas 452 layout (e.g., TFT structure) and the second region can have a second emissive areas 452 layout (e.g., TFT structure). For example, the first region can have the emissive areas 452 layout illustrated in FIG. 4B and the second region can have the emissive areas 452 layout illustrated in FIG. 4C.

In an example implementation, a first type of sensor (e.g., sensor 402) can be positioned under the first region and a second type of sensor (e.g., sensor 402) can be positioned under the second region. For example, a monochrome sensor can be positioned under the first region and a color sensor can be positioned under the second region.

The emissive areas 452 layout(s) illustrated in FIGS. 4B-4E illustrate a same positioning (e.g., layout) of the sub-pixels 442, 444, 446. However, example implementations are not limited thereto. FIGS. 4F-4K illustrate possible sub-pixel layouts. The illustrated layouts are just a few examples for the sake of brevity.

As illustrated in FIG. 4F, the emissive area 452-5 can include a red LED 442-5, a blue LED 444-5 and two green LEDs 446-5 clustered together within the emissive area 452-5 and having the same shape (e.g., circle). As illustrated in FIG. 4G, the emissive area 452-6 can include a red LED 442-6, a blue LED 444-6 and a green LED 446-6 linearly spread out within the emissive area 452-6 and having the same shape (e.g., rectangle). As illustrated in FIG. 4H, the emissive area 452-7 can include a red LED 442-7, a blue LED 444-7 and a green LED 446-7 linearly clustered together within the emissive area 452-5 and having the same shape (e.g., circle).

As illustrated in FIG. 4I, the emissive area 452-8 can include a red LED 442-8, a blue LED 444-8 and a green LED 446-8 clustered together and rotated within the emissive area 452-8 and having the same shape (e.g., triangle). As illustrated in FIG. 4J, the emissive area 452-9 can include three red LEDs 442-9 linearly clustered together within the emissive area 452-9 and having the same shape (e.g., rectangle). As illustrated in FIG. 4K, the emissive area 452-10 can include a red LED 442-10, a blue LED 444-10 and two green LEDs 446-10 clustered together within the emissive area 452-10 and having a different shape (e.g., circle and rectangle).

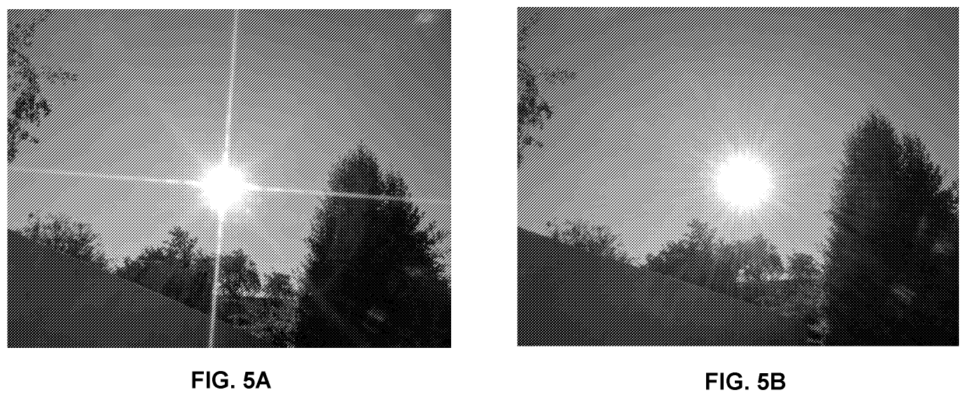

FIGS. 5A and 5B illustrate images generated from light transmitted through different display regions that have different shapes or layout patterns of opaque and/or diffracting structures with the same sensor configuration (or combination) according to at least one example embodiment. FIG. 5A illustrates an image captured by a camera (e.g., a monochrome or color camera) under a first region having a first layer structure or layout that influences the light that passes through the first region to the camera. FIG. 5B illustrates an image captured by a camera under a second region having a second layer structure or layout that influences the light that passes through the second region to the camera. The image in FIG. 5A has a first characteristic(s) (e.g., quality, sharpness, distortion, and the like) based on light distortion and the image in FIG. 5B has a second characteristic(s) (e.g., quality, sharpness, distortion, and the like) based on light distortion.

The light distortion associated the first layer structure or layout of the first region is different than the light distortion associated with the second layer structure or layout of the second region. Therefore, the first characteristics of the image in FIG. 5A can be different than the second characteristics of the image in FIG. 5B. For example, the image of FIG. 5A can have more defined features (e.g., be less blurry) of the elements (e.g., the sun, trees, and/or the like) in the image as compared to the image of FIG. 5B. FIGS. 5A and 5B illustrate that images captured with the same sensor when light is transmitted though different display layers to the sensor can have different characteristics. Some characteristics can be desirable (e.g., color representation of the scene or minimized blur) using a layer structure or layout and sensor type configuration. However, one of the images of FIG. 5A or 5B could have other desirable characteristics as compared to the images shown had an image been captured using a different sensor.

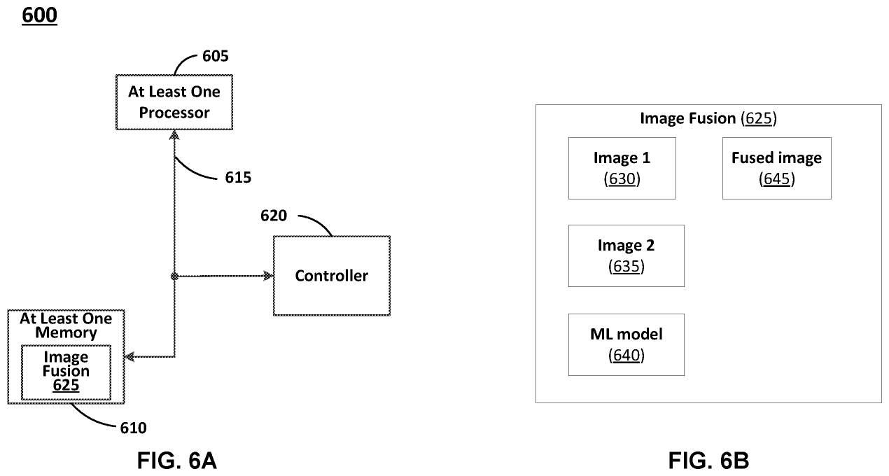

FIG. 6A illustrates a block diagram of a portion of an apparatus including an image processing system according to at least one example embodiment. As shown in FIG. 6A, the apparatus 600 includes at least one processor 605, at least one memory 610, and a controller 620. The at least one memory includes an image fusion 625 module. The at least one processor 605, the at least one memory 610, and the controller 620 are communicatively coupled via bus 615.

In the example of FIG. 6A, the apparatus 600 may include at least one computing device and should be understood to represent virtually any computing device configured to perform the techniques described herein. As such, the apparatus 600 may be understood to include various components that may be utilized to implement the techniques described herein, or different or future versions thereof. For example, the apparatus 600 is illustrated as including at least one processor 605, as well as at least one memory 610 (e.g., a computer readable storage medium).

Therefore, the at least one processor 605 may be utilized to execute instructions stored on the at least one memory 610. As such, the at least one processor 605 can implement the various features and functions described herein, or additional or alternative features and functions. The at least one processor 605 and the at least one memory 610 may be utilized for various other purposes. For example, the at least one memory 610 may be understood to represent an example of various types of memory and related hardware and software which can be used to implement any one of the modules described herein. According to example implementations, the apparatus 600 may be included in larger system (e.g., a server, a personal computer, a laptop computer, a mobile device and/or the like).

The at least one memory 610 may be configured to store data and/or information associated with the image fusion 625 module and/or the apparatus 600. The at least one memory 610 may be a shared resource. For example, the apparatus 600 may be an element of a larger system (e.g., a server, a personal computer, a mobile device, and the like). Therefore, the at least one memory 610 may be configured to store data and/or information associated with other elements (e.g., web browsing or wireless communication) within the larger system (e.g., an audio encoder with quantization parameter revision).

The controller 620 may be configured to generate various control signals and communicate the control signals to various blocks in the apparatus 600. The controller 620 may be configured to generate the control signals in order to implement searching using object recognition based on an image technique or other techniques described herein.

The at least one processor 605 may be configured to execute computer instructions associated with the image fusion 625 module, and/or the controller 620. The at least one processor 605 may be a shared resource. For example, the apparatus 600 may be an element of a larger system (e.g., a server, a personal computer, a mobile device, and the like). Therefore, the at least one processor 605 may be configured to execute computer instructions associated with other elements (e.g., serving web pages, web browsing or wireless communication) within the larger system.

FIG. 6B illustrates a block diagram of a module of the image processing system according to at least one example embodiment. As shown in FIG. 6B, the image fusion 625 module includes an image 630, an image 635, a machine learned (ML) model 640, and a fused image 645. The image 630 can include an image captured using a first sensor under a first region or display region as described above. The image 635 can include an image captured using a second sensor under a second region or display region as described above.

The ML model 640 can be executed (as programing code) by the at least one processor 605 with image 630 and image 635 used as input. The ML model 640 can be used to generate a fused image 645 based on image 630 and image 635. Generating fused image 645 based on image 630 and image 635 can include fusing image 630 and image 635 together.

The ML model 640 can be trained to keep preferred characteristics associated with image 630 and image 635 and to remove undesirable characteristics associated with image 630 and image 635. Therefore, fusing image 630 and image 635 together can include the desirable characteristics associated with image 630 and image 635 and not the undesirable characteristics associated with image 630 and image 635. The ML model 640 can include a convolutional neural network (CNN) as described in more detail below.

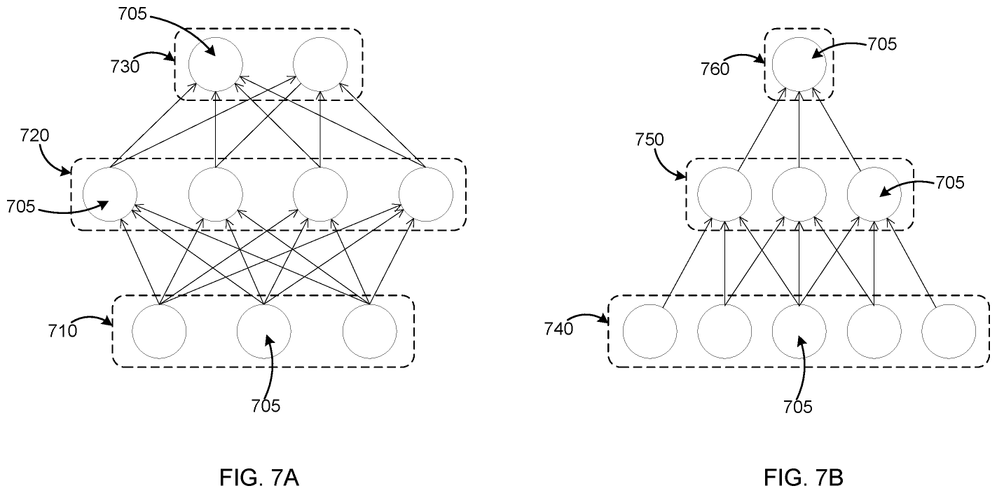

FIG. 7A illustrates layers in a convolutional neural network (CNN) with no sparsity constraints. FIG. 7B illustrates layers in a convolutional neural network (CNN) with sparsity constraints. With reference to FIGS. 7A and 7B, various configurations of neural networks for use in at least one example implementation will be described. An example layered neural network is shown in FIG. 7A. The layered neural network includes three layers 710, 720, 730. Each layer 710, 720, 730 can be formed of a plurality of neurons 705. In this implementation, no sparsity constraints have been applied. Therefore, all neurons 705 in each layer 710, 720, 730 are networked to all neurons 705 in any neighboring layers 710, 720, 730.

The example neural network shown in FIG. 7A is not computationally complex due to the small number of neurons 705 and layers. However, the arrangement of the neural network shown in FIG. 7A may not scale up to larger sizes of networks due to the density of connections (e.g., the connections between neurons/layers). In other words, the computational complexity can be too great as the size of the network scales and scales in a non-linear fashion. Therefore, it can be too computationally complex for all neurons 705 in each layer 710, 720, 730 to be networked to all neurons 705 in the one or more neighboring layers 710, 720, 730 if neural networks need to be scaled up to work on inputs with a large number of dimensions.

An initial sparsity condition can be used to lower the computational complexity of the neural network. For example, if a neural network is functioning as an optimization process, the neural network approach can work with high dimensional data by limiting the number of connection between neurons and/or layers. An example of a neural network with sparsity constraints is shown in FIG. 7B. The neural network shown in FIG. 7B is arranged so that each neuron 705 is connected only to a small number of neurons 705 in the neighboring layers 740, 750, 760. This can form a neural network that is not fully connected, and which can scale to function with higher dimensional data. For example, the neural network with sparsity constraints can be used as an optimization process for a model and/or generating a model for use in rating/downrating a reply based on the user posting the reply. The smaller number of connections in comparison with a fully networked neural network allows for the number of connections between neurons to scale in a substantially linear fashion.

In some implementations, neural networks that are fully connected or not fully connected but in different specific configurations to that described in relation to FIG. 7B can be used. Further, in some implementations, convolutional neural networks that are not fully connected and have less complexity than fully connected neural networks can be used. Convolutional neural networks can also make use of pooling or max-pooling to reduce the dimensionality (and hence complexity) of the data that flows through the neural network. Other approaches to reduce the computational complexity of convolutional neural networks can be used.

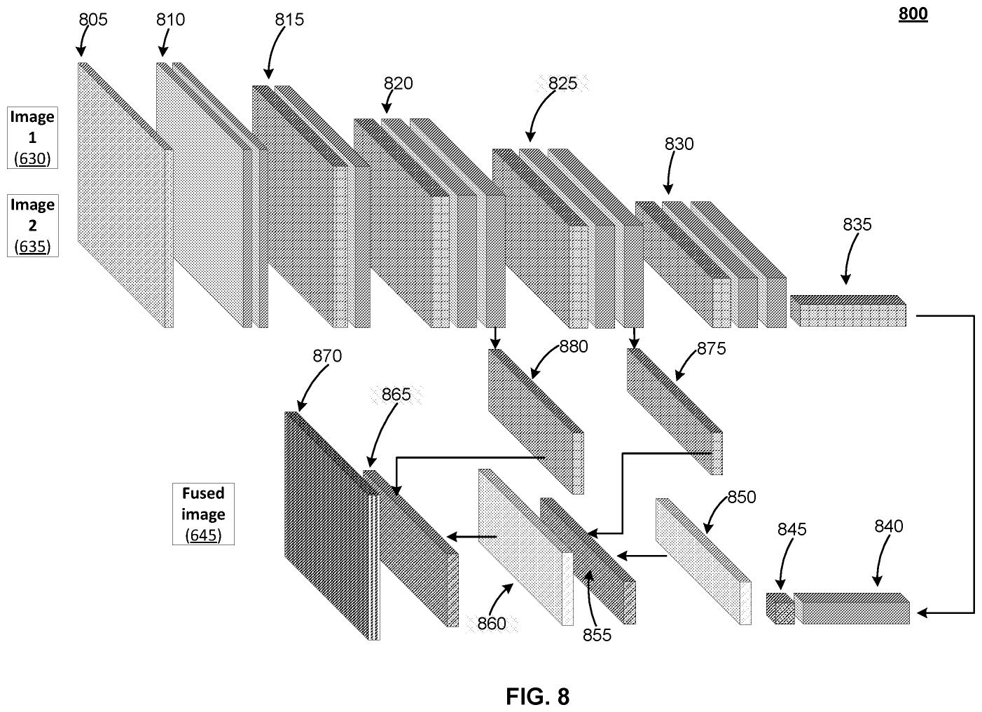

FIG. 8 illustrates a block diagram of a model according to an example embodiment. A ML model 800 can be configured to implement pixel-level image fusion. The ML model 800 can include, for example, a regression-type, a classification-type convolutional neural network (CNN). Pixel-level image fusion can generate a composite image from at least two images (e.g., image 630 and image 635) having complementary characteristics and information corresponding to the same scene (e.g., scene 305).

A convolution layer or convolution can be configured to extract features from an image. Features can be based on color, frequency domain, edge detectors, and/or the like. A convolution can have a filter (sometimes called a kernel) and a stride. For example, a filter can be a 1×1 filter (or 1×1×n for a transformation to n output channels, a 1×1 filter is sometimes called a pointwise convolution) with a stride of 1 which results in an output of a cell generated based on a combination (e.g., addition, subtraction, multiplication, and/or the like) of the features of the cells of each channel at a position of the M×M grid. In other words, a feature map having more than one depth or channels is combined into a feature map having a single depth or channel. A filter can be a 3×3 filter with a stride of 1 which results in an output with fewer cells each channel of the M×M grid or feature map.

The output can have the same depth or number of channels (e.g., a 3×3×n filter, where n=depth or number of channels, sometimes called a depthwise filter) or a reduced depth or number of channels (e.g., a 3×3×k filter, where k<depth or number of channels). Each channel, depth or feature map can have an associated filter. Each associated filter can be configured to emphasize different aspects of a channel. In other words, different features can be extracted from each channel based on the filter (this is sometimes called a depthwise separable filter). Other filters are within the scope of this disclosure.

Another type of convolution can include a combination of two or more convolutions. For example, a convolution can include a depthwise and pointwise separable convolution. This can include, for example, a convolution in two steps. The first step can include a depthwise convolution (e.g., a 3×3 convolution). The second step can include a pointwise convolution (e.g., a 1×1 convolution). The depthwise and pointwise convolution can include a separable convolution in that a different filter (e.g., filters to extract different features) can be used for each channel or ay each depth of a feature map. In an example implementation, the pointwise convolution can transform the feature map to include c channels based on the filter. For example, an 8×8×3 feature map (or image) can be transformed to an 8×8×256 feature map (or image) based on the filter. In some implementation more than one filter can be used to transform the feature map (or image) to an M×M×c feature map (or image).

A convolution can be linear. A linear convolution describes the output, in terms of the input, as being linear time-invariant (LTI). Convolutions can also include a rectified linear unit (ReLU). A ReLU is an activation function that rectifies the LTI output of a convolution and limits the rectified output to a maximum. A ReLU can be used to accelerate convergence (e.g., more efficient computation).

In an example implementation, the first type of convolution can include a 1×1 convolution and the second type of convolution can include a depthwise and pointwise separable convolution. Each of the plurality of convolution layers 820, 835, 840, 845, 850, 855, 860 can have a plurality of cells and at least one bounding box per cell. Convolution layers 815, 820, 825 and add layer 830 can be used to transform the image 630, 635 to a feature map that is equivalent in size to a feature map of the Conv_3 layer of the VGG-16 standard. In other words, convolution layers 815, 820, 825 and add layer 830 can transform the image 630, 635 to a 38×38×512 feature map.

In an example implementation, the ML model 800 CNN (e.g., regression-type CNN) can include a plurality of convolutional layers 805, 810, 815, 820, 825, 830, 835, 840, 845, 850, 855, 860, 865, and 870. The plurality of convolutional layers 805, 810, 815, 820, 825, 830, 835, 840, 845, 850, 855, 860, 865, and 870 can each correspond to at least one type of convolution layer. As shown in FIG. 8, the convolutional layer 805 can include a first convolution type, the convolutional layer 810 can include a second convolution type, the convolutional layers 815, 820, 825, 830 can include the second convolution type and a third convolution type, the convolutional layer 835 can include the third convolution type, the convolutional layer 840 can include a fourth convolution type, the convolutional layers 845, 855, 865 can include a fifth convolution type, the convolutional layers 850, 860 can include a sixth convolution type, and the convolutional layer 870 can include a seventh convolution type.

Each convolutional layer can generate many alternate convolutions, so the weight matrix is a tensor of x*y*n, where x*y the size of a sliding window (typically x=y) and n is the number of convolutions. The image 630 and the image 635 can be input to the CNN. In the first convolution type, the image 630 and the image 635 that can transform the images using a 224*224*3 weight matrix. The convolutional layer 810 can transform the resultant feature map using a 224*224*64 weight matrix, the convolutional layer 815 can transform the resultant feature map using a 112*112*128 weight matrix, the convolutional layer 820 can transform the resultant feature map using a 56*56*256 weight matrix, the convolutional layer 825 can transform the resultant feature map using a 28*28*512 weight matrix, the convolutional layer 830 can transform the resultant feature map using a 14*14*512 weight matrix, and the convolutional layer 835 can transform the resultant feature map using a 7*7*4096 weight matrix.

The next part of the ML model 800 can be configured to transform the feature map out from convolution layer 835 to an image with a size that is equivalent to the input image (e.g., image 630 or image 635). Convolution layer 840 receives a feature map from convolution layer 835 and transforms the feature map using a 7*7*4096 weight matrix. The convolutional layer 845 can transform the resultant feature map using a 7*7*classes weight matrix (where classes is a number of in the feature map), the convolutional layer 850 can transform the resultant feature map using a 14*14*classes weight matrix, the convolutional layer 855 can transform the resultant feature map together with the feature map output from convolution layer 825 (convolution layer 875) using a 14*14*classes weight matrix, the convolutional layer 860 can transform the resultant feature map using a 28*28*classes weight matrix, the convolutional layer 865 can transform the resultant feature map together with the feature map output from convolution layer 820 (convolution layer 880) using a 28*28*classes weight matrix, the convolutional layer 870 can transform the resultant feature map using a 224*224*classes weight matrix, the resultant feature map can include the output image (e.g., fused image 645).

Once a model (e.g., ML model 800) architecture has been designed (and/or in operation), the model should be trained (sometimes referred to as developing the model). The model can be trained using a plurality of images (e.g., scenes, products, portions of products, environmental objects (e.g., plants), portraits, and/or the like).

In an example implementation, a first sensor (e.g., an RGB sensor) and a first region of a device display can have first structure (e.g., a circular LED or transistor layout), and a second sensor (e.g., a monochrome sensor) and second region of the device display can have a second structure (e.g., a rectangular LED or transistor layout). The combination of the first sensor and the first region having the first structure can distort light transmitted through the first region and reaching the first sensor, such that an image generated from the light detected by the first sensor has first characteristic(s) (e.g., quality, sharpness, distortion, and the like). The combination of the second sensor and the second region having the second structure can distort light transmitted through the second region and reaching the second sensor, such that an image generated from the light detected by the second sensor has second characteristic(s) (e.g., quality, sharpness, distortion, and the like). The two resultant images can be combined (e.g., fused) together to generate a third image. The third image can be stored in a memory and/or displayed on the device display.

Image fusion using machine learning (ML) models can include two phases. In a first phase fusion, algorithms can be trained using supervised learning. In a second phase, the fusion algorithm can be deployed. As discussed above, example implementations can use a convolutional neural network (CNN) based fusion algorithm. In the first phase, the neural network can be trained. For example, two images can be input with first and second characteristics to the network. The output of the network can be compared with a ground truth image that has the most desirable characteristics we want the network to reproduce. An evaluation metric can be used to quantify the difference between the output and the ground truth images. This difference is used to update parameters of the network, which represents the training process. This process is repeated iteratively using a plurality of image examples until the difference between the output and the ground truth image is within a desirable margin and that concludes the training process.

As discussed above, a first camera can be a color camera generating a color image and a second camera can be a monochrome (or IR) camera generating a monochrome image. In example implementations, the CNN algorithm can result in selecting features from the color image and features from the monochrome image. For example, features associated with color can be selected from the color image and features associated with sharpness can be selected from the monochrome image. A region of the image that is not blurred by flares can be selected from the color image. These features can be selected based on what ground truth image we have shown to the network during the training process. Once the network is trained, it can be deployed in phase two to fuse any input images to output an image with desirable characteristics of the two input images.

This device display configuration can allow the device display to operate (e.g., show text, images, a background, and/or the like) over the entirety of the device display. In other words, the first region can include LEDs and/or transistors having a first structure or layout and the second region can include LEDs and/or transistors having a second structure or layout. The LEDs and/or transistors can be used throughout the device display to enable operation (e.g., the projection of light) of the display while also being configured to sense light used to generate an image. The display configuration of this device is preferable over a display configuration of device that removes (e.g., remove LEDs and/or transistors) a portion of the display to allow light to pass through to a sensor and over a device that includes a camera with moving parts used to position the camera to capture an image.

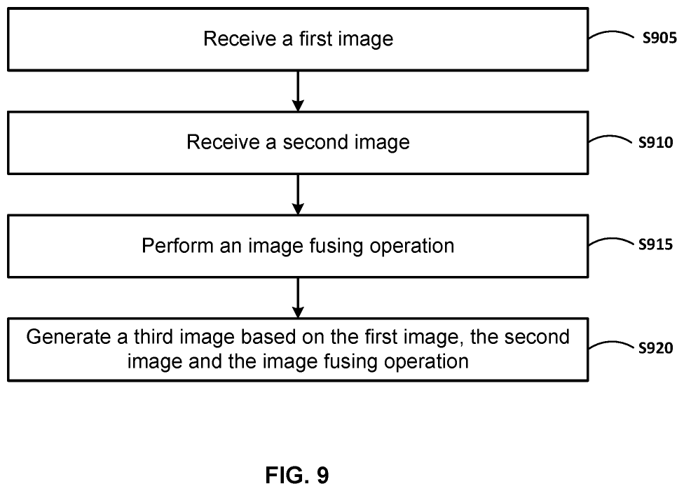

FIG. 9 illustrates a block diagram of a method for performing image fusion according to at least one example implementation. The steps described with regard to FIG. 9 may be performed due to the execution of software code stored in a memory (e.g., at least one memory 610) associated with an apparatus (e.g., as shown in FIG. 5A) and executed by at least one processor (e.g., at least one processor 605) associated with the apparatus. However, alternative embodiments are contemplated, such as a system embodied as a special purpose processor. Although the steps described below are described as being executed by a processor, the steps are not necessarily executed by the same processor. In other words, at least one processor may execute the steps described below with regard to FIG. 9.

As shown in FIG. 9, in step S905 a first image is received. For example, the first image can be received from an image processing pipeline associated with a device (e.g., a mobile device). The image pipeline can be configured to generate the first image based on a first signal received from first a camera and/or sensor. The first signal can represent light emitted from a scene. The first image can be received after the image pipeline has performed all image processing functions. Alternatively, the first image can be received after the image pipeline has performed a portion of the image processing functions (e.g., before image error correction). The first signal can be generated based on light that passes through a first region of a display of the device.

In step S910 a second image is received. For example, the second image can be received from an image processing pipeline associated with the device. The image pipeline can be configured to generate the second image based on a second signal received from a second camera and/or sensor. The second signal can represent light emitted from the scene. The second image can be received after the image pipeline has performed all image processing functions. Alternatively, the second image can be received after the image pipeline has performed a portion of the image processing functions (e.g., before image error correction). The second signal can be generated based on light that passes through a second region of the display of the device. The second region of the display of the device having a structure that is different than a structure of the first region of the display of the device.

In step S915 a third image is generated based on the first image, the second image and the image fusing operation. For example, the first image and the second image can be fused to generate the third image. Fusing can include using a ML model having the first image and the second image as input.

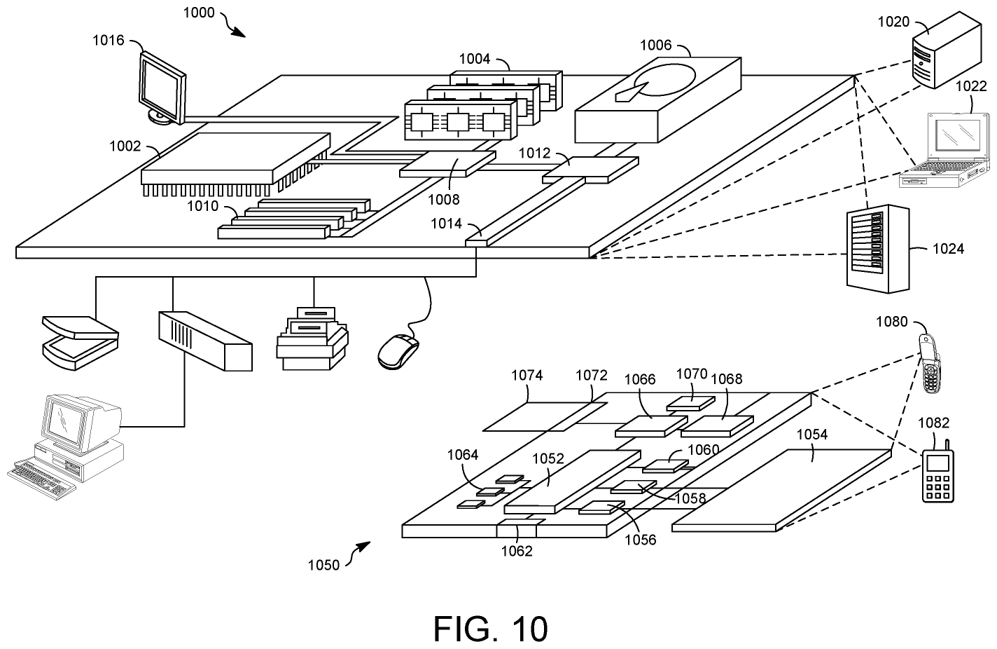

FIG. 10 shows an example of a computer device 1000 and a mobile computer device 1050, which may be used with the techniques described here. Computing device 1000 is intended to represent various forms of digital computers, such as laptops, desktops, workstations, personal digital assistants, servers, blade servers, mainframes, and other appropriate computers. Computing device 1050 is intended to represent various forms of mobile devices, such as personal digital assistants, cellular telephones, smart phones, and other similar computing devices. The components shown here, their connections and relationships, and their functions, are meant to be exemplary only, and are not meant to limit implementations of the inventions described and/or claimed in this document.

Computing device 1000 includes a processor 1002, memory 1004, a storage device 1006, a high-speed interface 1008 connecting to memory 1004 and high-speed expansion ports 1010, and a low speed interface 1012 connecting to low speed bus 1014 and storage device 1006. Each of the components 1002, 1004, 1006, 1008, 1010, and 1012, are interconnected using various busses, and may be mounted on a common motherboard or in other manners as appropriate. The processor 1002 can process instructions for execution within the computing device 1000, including instructions stored in the memory 1004 or on the storage device 1006 to display graphical information for a GUI on an external input/output device, such as display 1016 coupled to high speed interface 1008. In other implementations, multiple processors and/or multiple buses may be used, as appropriate, along with multiple memories and types of memory. Also, multiple computing devices 1000 may be connected, with each device providing portions of the necessary operations (e.g., as a server bank, a group of blade servers, or a multi-processor system).

The memory 1004 stores information within the computing device 1000. In one implementation, the memory 1004 is a volatile memory unit or units. In another implementation, the memory 1004 is a non-volatile memory unit or units. The memory 1004 may also be another form of computer-readable medium, such as a magnetic or optical disk.

The storage device 1006 is capable of providing mass storage for the computing device 1000. In one implementation, the storage device 1006 may be or contain a computer-readable medium, such as a floppy disk device, a hard disk device, an optical disk device, or a tape device, a flash memory or other similar solid state memory device, or an array of devices, including devices in a storage area network or other configurations. A computer program product can be tangibly embodied in an information carrier. The computer program product may also contain instructions that, when executed, perform one or more methods, such as those described above. The information carrier is a computer- or machine-readable medium, such as the memory 1004, the storage device 1006, or memory on processor 1002.

The high-speed controller 1008 manages bandwidth-intensive operations for the computing device 1000, while the low speed controller 1012 manages lower bandwidth-intensive operations. Such allocation of functions is exemplary only. In one implementation, the high-speed controller 1008 is coupled to memory 1004, display 1016 (e.g., through a graphics processor or accelerator), and to high-speed expansion ports 1010, which may accept various expansion cards (not shown). In the implementation, low-speed controller 1012 is coupled to storage device 1006 and low-speed expansion port 1014. The low-speed expansion port, which may include various communication ports (e.g., USB, Bluetooth, Ethernet, wireless Ethernet) may be coupled to one or more input/output devices, such as a keyboard, a pointing device, a scanner, or a networking device such as a switch or router, e.g., through a network adapter.

The computing device 1000 may be implemented in a number of different forms, as shown in the figure. For example, it may be implemented as a standard server 1020, or multiple times in a group of such servers. It may also be implemented as part of a rack server system 1024. In addition, it may be implemented in a personal computer such as a laptop computer 1022. Alternatively, components from computing device 1000 may be combined with other components in a mobile device (not shown), such as device 1050. Each of such devices may contain one or more of computing device 1000, 1050, and an entire system may be made up of multiple computing devices 1000, 1050 communicating with each other.

Computing device 1050 includes a processor 1052, memory 1064, an input/output device such as a display 1054, a communication interface 1066, and a transceiver 1068, among other components. The device 1050 may also be provided with a storage device, such as a microdrive or other device, to provide additional storage. Each of the components 1050, 1052, 1064, 1054, 1066, and 1068, are interconnected using various buses, and several of the components may be mounted on a common motherboard or in other manners as appropriate.

The processor 1052 can execute instructions within the computing device 1050, including instructions stored in the memory 1064. The processor may be implemented as a chipset of chips that include separate and multiple analog and digital processors. The processor may provide, for example, for coordination of the other components of the device 1050, such as control of user interfaces, applications run by device 1050, and wireless communication by device 1050.

Processor 1052 may communicate with a user through control interface 1058 and display interface 1056 coupled to a display 1054. The display 1054 may be, for example, a TFT LCD (Thin-Film-Transistor Liquid Crystal Display) or an OLED (Organic Light Emitting Diode) display, or other appropriate display technology. The display interface 1056 may comprise appropriate circuitry for driving the display 1054 to present graphical and other information to a user. The control interface 1058 may receive commands from a user and convert them for submission to the processor 1052. In addition, an external interface 1062 may be provide in communication with processor 1052, to enable near area communication of device 1050 with other devices. External interface 1062 may provide, for example, for wired communication in some implementations, or for wireless communication in other implementations, and multiple interfaces may also be used.

The memory 1064 stores information within the computing device 1050. The memory 1064 can be implemented as one or more of a computer-readable medium or media, a volatile memory unit or units, or a non-volatile memory unit or units. Expansion memory 1074 may also be provided and connected to device 1050 through expansion interface 1072, which may include, for example, a SIMM (Single In Line Memory Module) card interface. Such expansion memory 1074 may provide extra storage space for device 1050 or may also store applications or other information for device 1050. Specifically, expansion memory 1074 may include instructions to carry out or supplement the processes described above and may include secure information also. Thus, for example, expansion memory 1074 may be provide as a security module for device 1050 and may be programmed with instructions that permit secure use of device 1050. In addition, secure applications may be provided via the SIMM cards, along with additional information, such as placing identifying information on the SIMM card in a non-hackable manner.

The memory may include, for example, flash memory and/or NVRAM memory, as discussed below. In one implementation, a computer program product is tangibly embodied in an information carrier. The computer program product contains instructions that, when executed, perform one or more methods, such as those described above. The information carrier is a computer- or machine-readable medium, such as the memory 1064, expansion memory 1074, or memory on processor 1052, that may be received, for example, over transceiver 1068 or external interface 1062.

Device 1050 may communicate wirelessly through communication interface 1066, which may include digital signal processing circuitry where necessary. Communication interface 1066 may provide for communications under various modes or protocols, such as GSM voice calls, SMS, EMS, or MMS messaging, CDMA, TDMA, PDC, WCDMA, CDMA2000, or GPRS, among others. Such communication may occur, for example, through radio-frequency transceiver 1068. In addition, short-range communication may occur, such as using a Bluetooth, Wi-Fi, or other such transceiver (not shown). In addition, GPS (Global Positioning System) receiver module 1070 may provide additional navigation- and location-related wireless data to device 1050, which may be used as appropriate by applications running on device 1050.

Device 1050 may also communicate audibly using audio codec 1060, which may receive spoken information from a user and convert it to usable digital information. Audio codec 1060 may likewise generate audible sound for a user, such as through a speaker, e.g., in a handset of device 1050. Such sound may include sound from voice telephone calls, may include recorded sound (e.g., voice messages, music files, etc.) and may also include sound generated by applications operating on device 1050.

The computing device 1050 may be implemented in a number of different forms, as shown in the figure. For example, it may be implemented as a cellular telephone 1080. It may also be implemented as part of a smart phone 1082, personal digital assistant, or other similar mobile device.

In an example implementation, a device, a system, a non-transitory computer-readable medium (having stored thereon computer executable program code which can be executed on a computer system), and/or a method can perform a process with a device including a display including a main portion, a first region and a second region, the first region and the second region being in different positions within a boundary of the main portion, the first region having a first structure of light-blocking elements that distort light transmitted through the display, and the second region having a second structure of light-blocking elements that distort light transmitted through the display differently as compared to the first structure, a first light sensor positioned under the first region, the first light sensor being configured to capture a first image having at least one first characteristic, wherein the first characteristic depends on the first structure, a second light sensor positioned under the second region, the second light sensor being configured to capture a second image having at least one second characteristic, wherein the second characteristic depends on the second structure, and a memory including code that when executed by a processor causes the processor to generate a third image based on the first image and the second image.

Implementations can include one or more of the following features. For example, the first structure and the second structure can be based on a layout of red, green, and blue light-emitting diodes (LEDs) in the display. The first structure and the second structure can be based on a shape of at least one LED in an LED layer of the display. The display can include a plurality of layers, and one of the plurality of layers can include the light-blocking elements of the first region and the light-blocking elements of the second region. The first region can include a layout of a first array of LEDs of a first shape having a first arrangement of open space between the LEDs of the first array configured to allow light to pass through the display, the second region can include a layout of a second array of LEDs of a second shape having a second arrangement of open space between the LEDs of the second array to allow light to pass through the display, the first arrangement of open space can be configured to have a first transmissivity of light passing through the display, the second arrangement of open space can be configured to have a second transmissivity of light passing through the display, and the first transmissivity can be different than the second transmissivity.

The first light sensor can be a monochrome sensor, the second light sensor can be a color sensor, light-blocking elements of the first structure can include rectangular shaped elements, and light-blocking elements of the second structure can include circular shaped elements. The rectangular shaped elements can include first rectangle shaped elements having first dimensions and a second rectangle shaped elements having second dimensions, and the circular shaped elements can include first circular shaped elements having a first diameter and second circular shaped elements having a second diameter. The at least one first characteristic can include one or more of quality, sharpness, and distortion, and the at least one second characteristic can include one or more of quality, sharpness, and distortion. The code can include a machine learned model having at least one convolution layer.

In another example implementation, a device, a system, a non-transitory computer-readable medium (having stored thereon computer executable program code which can be executed on a computer system), and/or a method can perform a process with a method including generating a first image having at least one first characteristic based on a first sensor sensing light through a first region of a display, the first region having a first structure configured to impact light traversal through the display, generating a second image having at least one second characteristic based on a second sensor sensing light through a second region of the display, the second region having a second structure configured to impact the light traversing through the display differently as compared to the first structure, and generating a third image based on the first image and the second image.

Implementations can include one or more of the following features. For example, the at least one first characteristic can include one or more of quality, sharpness, and distortion, and the at least one second characteristic can include one or more of quality, sharpness, and distortion. The generating of the third image can include using a machine learned model having at least one convolution layer. The first light sensor can be one of a color sensor, a monochrome sensor, or an infrared sensor, and the second light sensor can be one of a color sensor, a monochrome sensor, or an infrared sensor. The first sensor can be a monochrome sensor, the second sensor can be a color sensor, a layout of the first structure can include rectangular shaped elements, and a layout of the second structure can include circular shaped elements. The rectangular shaped elements can include first rectangular shaped elements having first dimensions and a second rectangle having second dimensions, and the circular shaped elements can include first circular shaped elements having a first diameter and a second circle having a second diameter.

The light through the first region can be distorted based on the first structure, and the light through the second region can be distorted based on the second structure. The first region can include a layout of a first array of LEDs of a first shape having a first arrangement of open space between the LEDs of the first array configured to allow light to pass through the display, the second region can include a layout of a second array of LEDs of a second shape having a second arrangement of open space between the LEDs of the second array to allow light to pass through the display, the first arrangement of open space can be configured to have a first transmissivity of light passing through the display, the second arrangement of open space can be configured to have a second transmissivity of light passing through the display, and the first transmissivity can be different than the second transmissivity.

In yet another example implementation, a device, a system, a non-transitory computer-readable medium (having stored thereon computer executable program code which can be executed on a computer system), and/or a method can perform a process with a system including a display including a main portion, a first region and a second region, the first region and the second region being in different positions within a boundary of the main portion, the first region having a first structure of light-blocking elements that distort light transmitted through the display, and the second region having a second structure of light-blocking elements that distort light transmitted through the display differently as compared to the first structure, a monochrome sensor positioned under the first region, the monochrome sensor being used to capture a monochrome image having at least one first characteristic, a color sensor positioned under the second region, the color sensor being used to capture a color image having at least one second characteristic and a memory storing a set of instructions and a processor configured to execute the set of instructions to cause the system to generate a third image based on the monochrome image and the color image.

Implementations can include one or more of the following features. For example, a layout of the first structure can include rectangular shaped elements and a layout of the second structure can include circular shaped elements. The rectangular shaped elements can include a first rectangle having first dimensions and a second rectangle having second dimensions, and the circular shaped elements can include a first circle having a first diameter and a second circle having a second diameter.

While example embodiments may include various modifications and alternative forms, embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of the claims. Like numbers refer to like elements throughout the description of the figures.

Various implementations of the systems and techniques described here can be realized in digital electronic circuitry, integrated circuitry, specially designed ASICs (application specific integrated circuits), computer hardware, firmware, software, and/or combinations thereof. These various implementations can include implementation in one or more computer programs that are executable and/or interpretable on a programmable system including at least one programmable processor, which may be special or general purpose, coupled to receive data and instructions from, and to transmit data and instructions to, a storage system, at least one input device, and at least one output device. Various implementations of the systems and techniques described here can be realized as and/or generally be referred to herein as a circuit, a module, a block, or a system that can combine software and hardware aspects. For example, a module may include the functions/acts/computer program instructions executing on a processor (e.g., a processor formed on a silicon substrate, a GaAs substrate, and the like) or some other programmable data processing apparatus.

Some of the above example embodiments are described as processes or methods depicted as flowcharts. Although the flowcharts describe the operations as sequential processes, many of the operations may be performed in parallel, concurrently or simultaneously. In addition, the order of operations may be re-arranged. The processes may be terminated when their operations are completed but may also have additional steps not included in the figure. The processes may correspond to methods, functions, procedures, subroutines, subprograms, etc.

Methods discussed above, some of which are illustrated by the flow charts, may be implemented by hardware, software, firmware, middleware, microcode, hardware description languages, or any combination thereof When implemented in software, firmware, middleware or microcode, the program code or code segments to perform the necessary tasks may be stored in a machine or computer readable medium such as a storage medium. A processor(s) may perform the necessary tasks.

Specific structural and functional details disclosed herein are merely representative for purposes of describing example embodiments. Example embodiments, however, be embodied in many alternate forms and should not be construed as limited to only the embodiments set forth herein.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term and/or includes any and all combinations of one or more of the associated listed items.

It will be understood that when an element is referred to as being connected or coupled to another element, it can be directly connected or coupled to the other element or intervening elements may be present. In contrast, when an element is referred to as being directly connected or directly coupled to another element, there are no intervening elements present. Other words used to describe the relationship between elements should be interpreted in a like fashion (e.g., between versus directly between, adjacent versus directly adjacent, etc.).

The terminology used herein is for the purpose of describing particular embodiments only and is not intended to be limiting of example embodiments. As used herein, the singular forms a, an and the are intended to include the plural forms as well, unless the context clearly indicates otherwise. It will be further understood that the terms comprises, comprising, includes and/or including, when used herein, specify the presence of stated features, integers, steps, operations, elements and/or components, but do not preclude the presence or addition of one or more other features, integers, steps, operations, elements, components and/or groups thereof.

It should also be noted that in some alternative implementations, the functions/acts noted may occur out of the order noted in the figures. For example, two figures shown in succession may in fact be executed concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

Portions of the above example embodiments and corresponding detailed description are presented in terms of software, or algorithms and symbolic representations of operation on data bits within a computer memory. These descriptions and representations are the ones by which those of ordinary skill in the art effectively convey the substance of their work to others of ordinary skill in the art. An algorithm, as the term is used here, and as it is used generally, is conceived to be a self-consistent sequence of steps leading to a desired result. The steps are those requiring physical manipulations of physical quantities. Usually, though not necessarily, these quantities take the form of optical, electrical, or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

In the above illustrative embodiments, reference to acts and symbolic representations of operations (e.g., in the form of flowcharts) that may be implemented as program modules or functional processes include routines, programs, objects, components, data structures, etc., that perform particular tasks or implement particular abstract data types and may be described and/or implemented using existing hardware at existing structural elements. Such existing hardware may include one or more Central Processing Units (CPUs), digital signal processors (DSPs), application-specific-integrated-circuits, field programmable gate arrays (FPGAs) computers or the like.

It should be borne in mind, however, that all of these and similar terms are to be associated with the appropriate physical quantities and are merely convenient labels applied to these quantities. Unless specifically stated otherwise, or as is apparent from the discussion, terms such as processing or computing or calculating or determining of displaying or the like, refer to the action and processes of a computer system, or similar electronic computing device, that manipulates and transforms data represented as physical, electronic quantities within the computer system's registers and memories into other data similarly represented as physical quantities within the computer system memories or registers or other such information storage, transmission or display devices.

Note also that the software implemented aspects of the example embodiments are typically encoded on some form of non-transitory program storage medium or implemented over some type of transmission medium. The program storage medium may be magnetic (e.g., a floppy disk or a hard drive) or optical (e.g., a compact disk read only memory, or CD ROM), and may be read only or random access. Similarly, the transmission medium may be twisted wire pairs, coaxial cable, optical fiber, or some other suitable transmission medium known to the art. The example embodiments not limited by these aspects of any given implementation.

Lastly, it should also be noted that whilst the accompanying claims set out particular combinations of features described herein, the scope of the present disclosure is not limited to the particular combinations hereafter claimed, but instead extends to encompass any combination of features or embodiments herein disclosed irrespective of whether or not that particular combination has been specifically enumerated in the accompanying claims at this time.

What is claimed is:

1. A device comprising:
a display including a main portion, a first region and a second region,
the first region and the second region being in different positions within a boundary of the main portion,
the first region having a first structure of light-blocking elements that distort light transmitted through the display, and
the second region having a second structure of light-blocking elements that distort light transmitted through the display differently as compared to the first structure;
a first light sensor positioned under the first region, the first light sensor being configured to capture a first image having at least one first characteristic, wherein the first characteristic depends on the first structure;
a second light sensor positioned under the second region, the second light sensor being configured to capture a second image having at least one second characteristic, wherein the second characteristic depends on the second structure; and
a memory including code that when executed by a processor causes the processor to generate a third image based on the first image and the second image.

2. The device of claim 1, wherein the first structure and the second structure are based on a layout of red, green, and blue light-emitting diodes (LEDs) in the display.

3. The device of claim 1, wherein the first structure and the second structure are based on a shape of at least one LED in an LED layer of the display.

4. The device of claim 1, wherein
the display includes a plurality of layers, and
one of the plurality of layers includes the light-blocking elements of the first region and the light-blocking elements of the second region.

5. The device of claim 1, wherein
the first region includes a layout of a first array of LEDs of a first shape having a first arrangement of open space between the LEDs of the first array configured to allow light to pass through the display,
the second region includes a layout of a second array of LEDs of a second shape having a second arrangement of open space between the LEDs of the second array to allow light to pass through the display,
the first arrangement of open space is configured to have a first transmissivity of light passing through the display,
the second arrangement of open space is configured to have a second transmissivity of light passing through the display, and
the first transmissivity is different than the second transmissivity.

6. The device of claim 1, wherein
the first light sensor is a monochrome sensor,
the second light sensor is a color sensor,
light-blocking elements of the first structure include rectangular shaped elements, and
light-blocking elements of the second structure include circular shaped elements.

7. The device of claim 6, wherein
the rectangular shaped elements include first rectangle shaped elements having first dimensions and a second rectangle shaped elements having second dimensions, and
the circular shaped elements include first circular shaped elements having a first diameter and second circular shaped elements having a second diameter.

8. The device of claim 1, wherein
the at least one first characteristic includes one or more of quality, sharpness, and distortion, and
the at least one second characteristic includes one or more of quality, sharpness, and distortion.

9. The device of claim 1, wherein the code includes a machine learned model having at least one convolution layer.

10. A method comprising:
generating a first image having at least one first characteristic based on a first sensor sensing light through a first region of a display, the first region having a first structure configured to impact light traversal through the display;
generating a second image having at least one second characteristic based on a second sensor sensing light through a second region of the display, the second region having a second structure configured to impact the light traversing through the display differently as compared to the first structure; and
generating a third image based on the first image and the second image.

11. The method of claim 10, wherein
the at least one first characteristic includes one or more of quality, sharpness, and distortion, and
the at least one second characteristic includes one or more of quality, sharpness, and distortion.

12. The method of claim 10, wherein the generating of the third image includes using a machine learned model having at least one convolution layer.

13. The method of claim 10, wherein
the first light sensor is one of a color sensor, a monochrome sensor, or an infrared sensor, and
the second light sensor is one of a color sensor, a monochrome sensor, or an infrared sensor.

14. The method of claim 10, wherein
the first sensor is a monochrome sensor,
the second sensor is a color sensor,
a layout of the first structure includes rectangular shaped elements, and
a layout of the second structure includes circular shaped elements.

15. The method of claim 14, wherein
the rectangular shaped elements include first rectangular shaped elements having first dimensions and a second rectangle having second dimensions, and
the circular shaped elements include first circular shaped elements having a first diameter and a second circle having a second diameter.

16. The method of claim 10, wherein
the light through the first region is distorted based on the first structure, and
the light through the second region is distorted based on the second structure.

17. The method of claim 10, wherein
the first region includes a layout of a first array of LEDs of a first shape having a first arrangement of open space between the LEDs of the first array configured to allow light to pass through the display,
the second region includes a layout of a second array of LEDs of a second shape having a second arrangement of open space between the LEDs of the second array to allow light to pass through the display,
the first arrangement of open space is configured to have a first transmissivity of light passing through the display,
the second arrangement of open space is configured to have a second transmissivity of light passing through the display, and the first transmissivity is different than the second transmissivity.

18. A system comprising:
a display including a main portion, a first region and a second region,
the first region and the second region being in different positions within a boundary of the main portion,
the first region having a first structure of light-blocking elements that distort light transmitted through the display, and
the second region having a second structure of light-blocking elements that distort light transmitted through the display differently as compared to the first structure;
a monochrome sensor positioned under the first region, the monochrome sensor being used to capture a monochrome image having at least one first characteristic;
a color sensor positioned under the second region, the color sensor being used to capture a color image having at least one second characteristic;
a memory storing a set of instructions; and
a processor configured to execute the set of instructions to cause the system to generate a third image based on the monochrome image and the color image.

19. The system of claim 18, wherein
a layout of the first structure includes rectangular shaped elements, and
a layout of the second structure includes circular shaped elements.

20. The system of claim 19, wherein
the rectangular shaped elements include a first rectangle having first dimensions and a second rectangle having second dimensions, and
the circular shaped elements include a first circle having a first diameter and a second circle having a second diameter.
